(19) United States
(12) Patent Application Publication
(10) Pub. No.: US 2005/0088168 A1
(43) Pub. Date: Apr. 28, 2005

(54) Control module for use with a test probe

(76) Inventor: Kelly J. Reasoner, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/695,555

(22) Filed: Oct. 28, 2003

(51) Int. Cl. G01R 1/00

(52) U.S. Cl. 324/158.1

(57) ABSTRACT

A control module for an electronic test probe is built including a switch or other control device coupled to the test equipment, and electrically isolated from the probe tip, such that a user may make a measurement with the probe, and then without moving the probe, activate the control device to change the configuration of the test equipment. This allows a user to make different measurements of the same part of a device without having to remove the probe from the device to change the configuration of the test equipment. Also, since the control device is electrically isolated from the probe tip, activating the control device does not electrically interfere with the voltage at the probe tip. Further, the control device body is configured to non-permanently mechanically couple with the test probe, so that the same control device may be used with a plurality of different test probes.

### FIELD OF THE INVENTION

The present invention relates generally to the field of test equipment probes, and more particularly to the field of controlling test equipment from probes.

### BACKGROUND OF THE INVENTION

Modern electrical test equipment, such as multi-meters and oscilloscopes, use remote probes between the test equipment and the device under test. This allows the test equipment to sit on a shelf or lab bench away from the device under test so that the user may easily make various measurements of the device by moving only the small probe instead of the more bulky test equipment.

Often the test equipment is placed on a shelf or in a rack near the device under test, but far enough away to allow the user free movement around the device. In making a series of measurements the user typically configures the test equipment for the desired measurement and then places the probe (or probes) on the device under test to make the actual measurement. If the user desires to make a similar measurement of a different part of the device, the configuration of the test equipment may be left unchanged, and the user simply moves the probe (or probes) to a different part of the device and makes the measurement. If the user desires to make different measurements of the same part of the device, they may need to change the configuration of the test equipment between the different measurements. This involves setting down the probe (or probes), changing the configuration of the test equipment, and replacing the probe (or probes) to the same part of the device under test. In a complex device, it may be tedious and difficult to properly place the probes to make a measurement. Thus, there is a need in the art for an apparatus allowing a user to change the configuration of test equipment without having to remove the probe (or probes) from the device under test.

While making delicate measurements a user often will want to save or print a copy of the present display or data from a piece of test equipment. Currently, the user must have one hand free to save or print the data. If two hands are required to take the measurement, or if the test equipment is located out of reach, an additional person is required to save or print the data from the test equipment. Thus, there is a need in the art for an apparatus allowing a user to save or print data from test equipment from the probe itself instead of having to physically reach the test equipment.

### SUMMARY OF THE INVENTION

A control module for an electronic test probe is built including a switch or other control device coupled to the test equipment, and electrically isolated from the probe tip, such that a user may make a measurement with the probe, and then without moving the probe, activate the control device to change the configuration of the test equipment. This allows a user to make different measurements of the same part of a device without having to remove the probe from the device to change the configuration of the test equipment. Also, since the control device is electrically isolated from the probe tip, activating the control device does not electrically interfere with the voltage at the probe tip. Further, the control device body is configured to non-permanently mechanically couple with the test probe, so that the same control device may be used with a plurality of different test probes.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1 is a drawing of a portion of an embodiment of an electrical test probe and a control module, before non-permanent attachment of the control module to the test probe according to the present invention.

FIG. 2 is a drawing of a portion of an embodiment of an electrical probe and a control module including a mode display, before non-permanent attachment of the control module to the test probe according to the present invention.

FIG. 3 is a cut-away drawing of a portion of an embodiment of an electrical probe including a non-permanently attached control module according to the present invention.

FIG. 4 is a cut-away drawing of a portion of an embodiment of an electrical probe including a non-permanently attached control module including a mode display according to the present invention.

FIG. 5 is a cut-away drawing of a portion of an embodiment of an electrical probe including a non-permanently attached control module including a mode display and a communication port according to the present invention.

FIG. 6 is a cut-away drawing of a portion of an embodiment of an electrical probe including a non-permanently attached control module including a mode display according to the present invention.

### DETAILED DESCRIPTION

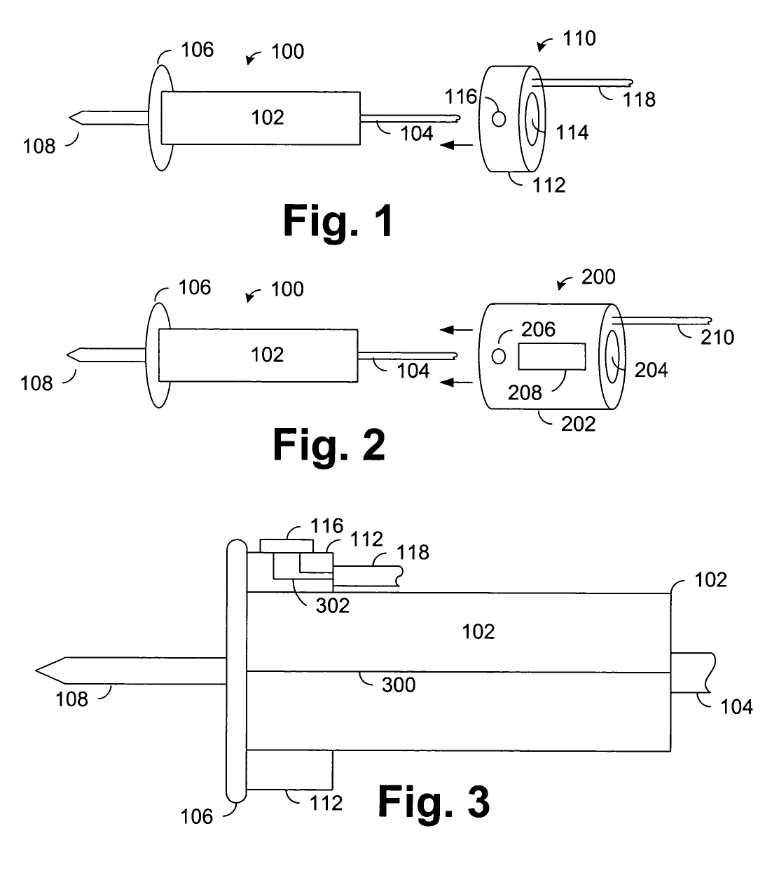

FIG. 1 is a drawing of a portion of an embodiment of an electrical test probe and a control module, before non-permanent attachment of the control module to the test probe according to the present invention. A probe 100 comprising a probe body 102, an optional finger guard 106, a cable 104 electrically connecting the probe to test equipment, and a probe tip 108, is improved by the addition of a non-permanently attachable control module 110. In this example embodiment of the present invention the control module 110 includes an opening 114 within the control module body 112 configured to fit over the probe body 102. In this example embodiment of the present invention the control module 110 includes a control device 116 such as a switch. Those of skill in the art will recognize that while a switch is shown in this figure for simplicity, many other control devices may be used within the scope of the present invention. While this example embodiment of the present invention includes a control module 110 configured to slide over the outside of the probe body 102, other embodiments of the present invention may other means for non-permanently attaching the control module 110 to the probe 100. For example, a control module 110 may use an elastic band, or a patch of hook and loop fabric for non-permanent attachment to the probe 100. In this example configuration, the probe 100 is attached to the test equipment through a cable 104 between the probe body 102 and the test equipment. Note that within the scope of the present invention there are other mechanisms instead of a cable to send probe data and configuration data to the test equipment. For example, infrared light emitting diodes (LEDs), or radio waves may be reasonable mechanisms to couple the probe with the test equipment in some configurations. (FIG. 5 is an example embodiment of the present invention including a communication port 500 for transfer of data between the test probe and the test equipment.) Within the probe body are electrical connections between the cable 104 (or the communication port 500) and the probe tip 108. A second cable 118 is used to electrically couple the control device 116 within the control module 110 to the test equipment. Note that through the use of separate cables the control device 116 is electrically isolated from the probe tip 108. This prevents activation of the control device 110 from having an unwanted effect on the measurement being taken. An optional finger guard 106 is mechanically attached to the probe body 102 to keep the users fingers from contacting the probe tip 108. The control device 116 may be a simple push button switch as shown here, a rotary switch, an optoelectronic motion controller, or another method of controlling the test equipment. For example, a simple push button may be configured to cycle the test equipment through a series of configurations and the user would repeatedly press the button until the desired configuration is reached. A small rotary switch may have several different configurations encoded such that rotating the switch changes the configurations on the test equipment. Further, the configurations represented by rotational direction of the rotary switch may be programmable by a user. An optoelectronic motion encoder similar to those used on computer mice may be used such that the user turns a wheel or ball to change the configurations of the test equipment. Using a small trackball or a joystick, such as those often used in laptop personal computers, two different variables may be changed at the same time. For example, on an oscilloscope probe, a small joystick may be configured such that the x-axis controls the voltage sensitivity of the oscilloscope and the y-axis controls the time domain. This would allow the user to vary both sensitivity and frequency of the oscilloscope measurement without having to release the probe. Also, any combination of buttons, switches, wheels, balls and joysticks may be used if room allows on the probe, greatly expanding the possible variables that may be controlled without releasing the probe. Further, the control device is not limited to selecting configurations of the test equipment. In some embodiments of the present invention the control device may be designed to save a current reading or to print a display of the data, or to print a configuration summary. Thus, within the scope of the present invention, one embodiment may have both a joystick for controlling the configuration of the test equipment along with a push button for saving the present data or printing a representation of the data display of the test equipment to a printer.

FIG. 2 is a drawing of a portion of an embodiment of an electrical probe and a control module including a mode display, before non-permanent attachment of the control module to the test probe according to the present invention. This example configuration comprises the same elements as the probe shown in FIG. 1 with the addition of a mode display 208 incorporated within the control module 200 in addition to a control device 206 mechanically coupled with the control module body 202. In this example embodiment of the present invention the control module 200 includes an opening 204 configured to fit over the probe body 102. This mode display 208 may be a small liquid crystal diode (LCD) display, an array of light emitting diodes (LED's), a LED numeric display, or similar display devices. Anything that gives an indication of the configuration of the test equipment may be used as a mode display 208. The test equipment configuration may be represented by alphanumeric digits, color, position, or any other indication possible on such displays. A simple row of LED's below printed configuration information may be an inexpensive display method. Such a mode display 208 would allow the user to verify that the test equipment is in the proper mode for the current measurement without having to look at the face of the test equipment itself.

FIG. 3 is a cut-away drawing of a portion of an embodiment of an electrical probe including a non-permanently attached control module according to the present invention. This example embodiment of the present invention is equivalent to that shown in FIG. 1 with the internal connections within the probe body 102 and the control module body 112 shown. In this example embodiment, the probe tip 108 is electrically connected to the cable 104 through a wire 300. In addition the control device 110 is electrically connected to a second cable 118 through one or more control wires 302. The elements connecting the probe tip 108 to the cable 104 may vary according to the needs of the probe and are not critical elements of the present invention. Likewise, the control wires connecting the control device 116 to the test equipment through the second cable 118 may vary in number and type within the scope of the present invention. Note, however, that the wires connecting the control device 116 to the test equipment are electrically isolated from the wire or wires connecting the probe tip 108 to the test equipment.

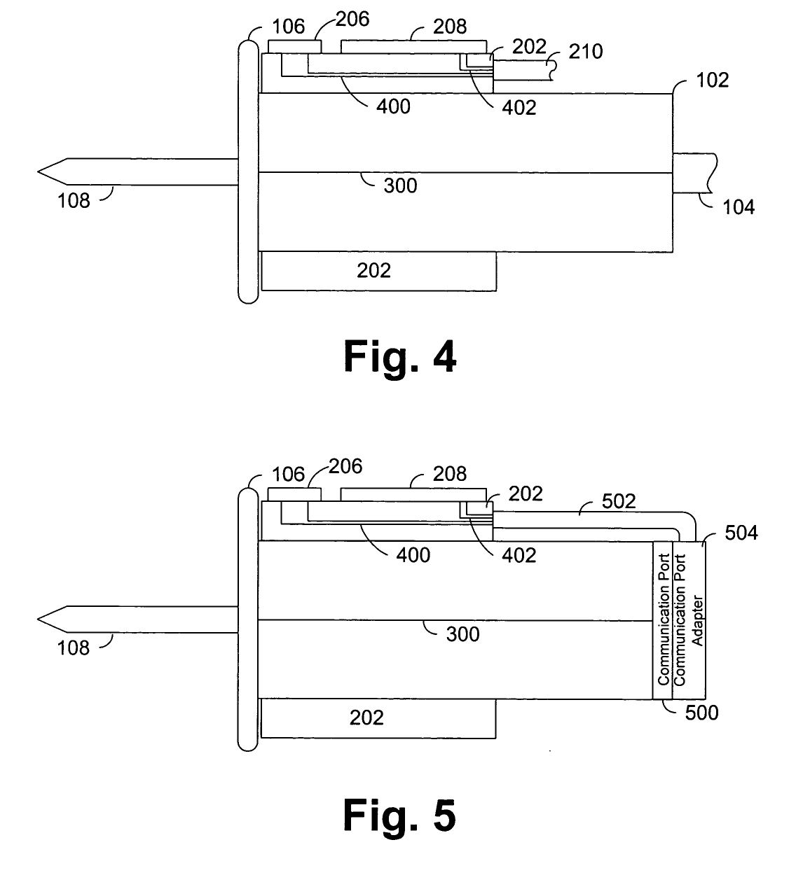

FIG. 4 is a cut-away drawing of a portion of an embodiment of an electrical probe including a non-permanently attached control module including a mode display according to the present invention. This example embodiment of the present invention is equivalent to that shown in FIG. 2 with the internal connections within the probe body 102 and the control module body 202 shown. In this example embodiment, the probe tip 108 is electrically connected to the cable 104 through a wire 300. In addition the control device 206 is electrically connected to a second cable 210 through one or more control wires 400. The elements connecting the probe tip 108 to the cable 104 may vary according to the needs of the probe and are not critical elements of the present invention. Likewise, the control wires 400 connecting the control device 206 to the test equipment through the second cable 210 may vary in number and type within the scope of the present invention. Also, the mode display 208 is connected to the test equipment through the second cable 210 by at least one display wire 402. The number and type of these display wires 402 may vary greatly within the scope of the present invention. Note, however, that the control wires connecting the control device 206 to the test equipment are electrically isolated from the wire or wires connecting the probe tip 108 to the test equipment. In some embodiments of the present invention, such as that shown in FIG. 5, there may not need to be any wires connecting the probe 100 to the test equipment.

FIG. 5 is a cut-away drawing of a portion of an embodiment of an electrical probe including a non-permanently attached control module including a mode display and a communication port according to the present invention. The example embodiment of the present invention shown in FIG. 5 is identical to that of FIG. 4 except that the cable 104 has been replaced with a communication port 500. This communication port 500 may be an infrared LED or other wireless communication port that enables the probe 100 to send test data and configuration data to a piece of test equipment and optionally receive communication from the test equipment. For example, the test equipment may need to signal the probe when it is ready to receive data, or to confirm configuration changes or other control signals sent to the test equipment from the test probe. The control wires 400 and display wires 402 may be electrically connected to a communication port adapter 504 through a second wire 502. In an example embodiment of the present invention the communication port adapter 504 passes through the output of the communication port 500 while merging in the data transferring between the control device 206 to the test equipment, and between the mode display 208 and the test equipment. Note that while the control data may be merged with the test probe data, care is taken that the two data signals are independent of each other, such that changes in the state of the control device 206 do not affect the voltage seen at the probe tip 108 and communicated to the test equipment.

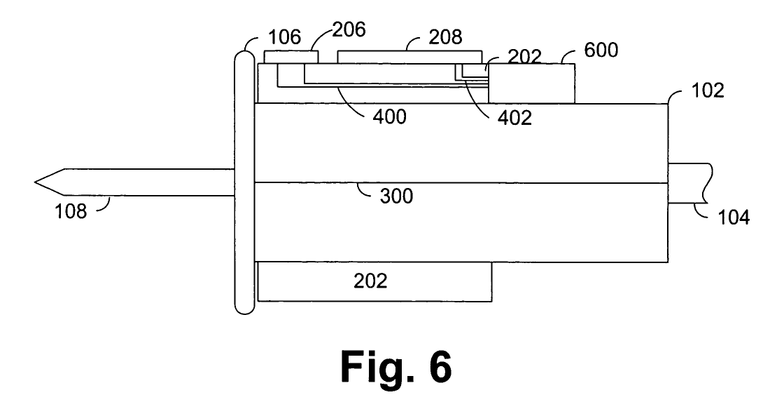

FIG. 6 is a cut-away drawing of a portion of an embodiment of an electrical probe including a non-permanently attached control module including a mode display according to the present invention. This example embodiment of the present invention is equivalent to that shown in FIG. 4 however the control module is connected to the test instrument through a network interface 600. Numerous modem test instruments have the ability to be programmed or controlled through a computer network interface. In this example embodiment of the present invention the control module controls the test instrument through this network interface 600. Those of skill in the art will recognize that there are a variety of network interfaces and protocols available to the designer. This embodiment of the present invention may use an Ethernet or other network protocol (or perhaps a proprietary interface specific to the test equipment used), and may be hard wired to the network, or configured to operate in a wireless network within the scope of the present invention. In this example embodiment, the probe tip 108 is electrically connected to the cable 104 through a wire 300. In addition the control device 206 is electrically connected to the test instrument through a network interface 600. The elements connecting the probe tip 108 to the cable 104 may vary according to the needs of the probe and are not critical elements of the present invention. Likewise, the control wires connecting the control device 206 to the test equipment through the network interface 600 may vary in number and type within the scope of the present invention. Also, the mode display 208 is connected to the test equipment through the network interface 600 by at least one display wire 402. The number and type of these display wires 402 may vary greatly within the scope of the present invention. Note, however, that the control wires 400 connecting the control device 206 to the test equipment are electrically isolated from the wire or wires connecting the probe tip 108 to the test equipment. In some embodiments of the present invention, such as that shown in FIG. 5, there may not need to be any wires connecting the probe 100 to the test equipment.

The foregoing description of the present invention has been presented for purposes of illustration and description. It is not intended to be exhaustive or to limit the invention to the precise form disclosed, and other modifications and variations may be possible in light of the above teachings. The embodiments were chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

1. A control module for an electrical test probe comprising;
a control module body, wherein said control module body is configured to non-permanently mechanically couple to an electrical test probe;
a control device mechanically coupled to said control module body, and electrically isolated from a probe tip within said electrical test probe, wherein said control device is capable of being non-permanently electrically coupled to a test instrument; and
a mode display mechanically coupled to said control module body and electrically coupled to said test instrument, said mode display visually representing a configuration of said test instrument.

2. A control module for an electrical test probe as recited in claim 1 wherein;
said mode display is a liquid crystal display device.

3. A control module for an electrical test probe as recited in claim 1 wherein;
said mode display is a light emitting diode display device.

4. A control module for an electrical test probe as recited in claim 1 wherein;
said mode display is one or more light emitting diodes.

5. A control module for an electrical test probe as recited in claim 1 wherein;
said mode display is an electroluminescent display device.

6-10. (canceled)

11. A control module for an electrical test probe comprising:
a control module body configured to non-permanently mechanically couple to an electrical test probe body;
a control device mechanically coupled to said control module body and electrically isolated from a probe tip of said electrical test probe, wherein said control device, when activated, activates a function of an external electrical test instrument;
a cable electrically coupled to said control module, mechanically coupled to said control module body, and electrically coupled to said control device, and non-permanently electrically and mechanically coupled to said test instrument; and
a mode display mechanically coupled to said control module body and electrically coupled to said test instrument visually representing a configuration of said test instrument.

12. A control module for an electrical test probe as recited in claim 11 wherein;
said mode display is a liquid crystal display device.

13. A control module for an electrical test probe as recited in claim 11 wherein;
said mode display is a light emitting diode display device.

14. A control module for an electrical test probe as recited in claim 11 wherein;
said mode display is one or more light emitting diodes.

15. A control module for an electrical test probe as recited in claim 11 wherein;
said mode display is an electroluminescent display device.

16-20. (canceled)
